(19) United States
(12) Patent Application Publication
(10) Pub. No.: US 2024/0305401 A1
(43) Pub. Date: Sep. 12, 2024

(54) METHOD FOR DATA COMPRESSION BASED ON PRESET RULE, DEVICE, AND MEDIUM

(71) Applicant: SHENZHEN ZHI HUI LIN NETWORK TECHNOLOGY CO., LTD., Shenzhen Guangdong (CN)

(72) Inventors: Behzad MOGHADDAM SARDROUD, Shenzhen Guangdong (CN); Hamed KALANTARI, Shenzhen Guangdong (CN); Behzad KALANTARI, Shenzhen Guangdong (CN); Xiaoduan DING, Shenzhen Guangdong (CN); Kun HUANG, Shenzhen Guangdong (CN); Yan YIN, Shenzhen Guangdong (CN)

(73) Assignee: SHENZHEN ZHI HUI LIN NETWORK TECHNOLOGY CO., LTD., Shenzhen Guangdong (CN)

(21) Appl. No.: 18/667,085

(22) Filed: May 17, 2024

Related U.S. Application Data
(63) Continuation of application No. PCT/CN2022/126267, filed on Oct. 19, 2022.

(30) Foreign Application Priority Data
Nov. 18, 2021 (CN) 202111367774.4

(51) Int. Cl. H04L 1/00; H04L 69/04

(52) U.S. Cl. CPC H04L 1/0006; H04L 69/04

(57) ABSTRACT

A method for data compression based on a preset rule, a device, and a medium are provided. The method includes the following. Original data is acquired. A binary conversion on the original data is performed to obtain a binary data. The binary data is scanned, the binary data is matched with the preset rule, and binary data that is successfully matched with the preset rule is separated into a data split. The data split is abbreviated to obtain an abbreviated data split. Abbreviated data is sent, where the abbreviated data includes the abbreviated data split.

### CROSS-REFERENCE TO RELATED APPLICATION(S)

This application is a continuation of International Application No. PCT/CN2022/126267, filed Oct. 19, 2022, which claims priority to Chinese Patent Application No. 202111367774.4, filed Nov. 18, 2021, the entire disclosures of both of which are hereby incorporated by reference.

### TECHNICAL FIELD

The present disclosure relates to the field of data processing technology, in particular, to a method for data compression based on a preset rule, a device, and a medium.

### BACKGROUND

With the rapid development of our society and economy, and the continuous improvement of people's living standard, data communication technology has been widely popularized and applied in all walks of life. With the growth of data transmission volume, there is an increasingly high requirement for the speed of data transmission on the market.

### SUMMARY

In a first aspect, embodiments of the disclosure provide a method for data compression based on a preset rule. The method includes the following. Original data is acquired. A binary conversion on the original data is performed to obtain binary data. The binary data is scanned, the binary data is matched with the preset rule, and binary data that is successfully matched with the preset rule is separated into a data split. The data split is abbreviated to obtain an abbreviated data split. Abbreviated data is sent, where the abbreviated data includes the abbreviated data split.

In a second aspect, embodiments of the disclosure provide an electronic device. The electronic device includes a processor, a memory, and a computer-executable instruction that is stored in the memory and executable on the processor. The computer-executable instruction, when executed, causes the electronic device to execute some or all of the steps in any method in the first aspect.

In a third aspect, embodiments of the disclosure provide a non-transitory computer-readable storage medium. The non-transitory computer-readable storage medium stores a computer instruction, and the computer instruction, when executed on a communication device, causes the communication device to execute some or all of the steps in any of the method in the first aspect.

### BRIEF DESCRIPTION OF THE DRAWINGS

In order to describe technical solutions in the related art or embodiments of the disclosure more clearly, the following will give a brief introduction to the accompanying drawings required for describing the related art or embodiments. Apparently, the accompanying drawings hereinafter described are merely some embodiments of the disclosure. Based on these drawings, those of ordinary skills in the art can also obtain other drawings without creative effort.

FIG. 1 is a structural arrangement diagram of a data transmission system.

FIG. 2 is a flowchart of a method for data compression based on a preset rule provided in an embodiment of the disclosure.

FIG. 3 is an arrangement diagram of a system for data compression based on a preset rule applied by an embodiment of the disclosure.

FIG. 4 is a schematic diagram of a method for data compression based on a preset rule provided in an embodiment of the disclosure.

FIG. 5 is a schematic diagram of another method for data compression based on a preset rule provided in an embodiment of the disclosure.

FIG. 6 is a schematic diagram of another method for data compression based on a preset rule provided in an embodiment of the disclosure.

FIG. 7 is a structural diagram of an apparatus for data compression based on a preset rule provided in an embodiment of the disclosure.

FIG. 8 is a schematic structural diagram of a server for hardware operating environment of an electronic device provided in an embodiment of the disclosure.

### DETAILED DESCRIPTION

The following will illustrate technical solutions of embodiments of the disclosure with reference to the accompanying drawings of embodiments of the disclosure. Apparently, embodiments described herein are merely some embodiments, rather than all embodiments, of the disclosure. Based on the embodiments of the disclosure, all other embodiments obtained by those of ordinary skills in the art without creative effort shall fall within the protection scope of the disclosure.

The terms “first”, “second”, and the like used in the specification, the claims, and the accompany drawings of the disclosure are used to distinguish different objects rather than describe a particular order. In addition, the terms “include”, “comprise”, as well as variations thereof are intended to cover non-exclusive inclusion. For example, a process, a method, a system, a product, or a device that includes a series of steps or units is not limited to the listed steps or units, but optionally further includes an unlisted step or unit, or optionally further includes another step or unit inherent to the process, the method, the product, or the device.

Reference herein to an “embodiment” means that particular features, structures, or characteristics described in connection with embodiments may be included in at least an embodiment of the present disclosure. The phrase appearing in various positions in the specification does not necessarily refer to the same embodiment, nor is it an independent or alternative embodiment that is mutually exclusive with other embodiments. Those of ordinary skills in the art explicitly and implicitly understand that the embodiments described in present disclosure can be combined with other embodiments.

In order to improve the speed of data transmission, data is usually split to achieve the purpose of compressing the data. As for current methods for data compression, data is usually split into multiple data splits with the same size for data transmission. However, in this method, those data splits show no regularity in data content, and thus a method for data compression is irregular for each of the multiple data splits. In this case, a large amount of time may be spent to match methods for data compression in the process of compressing a large number of data splits.

Therefore, with those current methods for data compression, the speed of data transmission is difficult to be improved.

The following will introduce the application scenarios involved in embodiments of the disclosure with reference to the accompanying drawings.

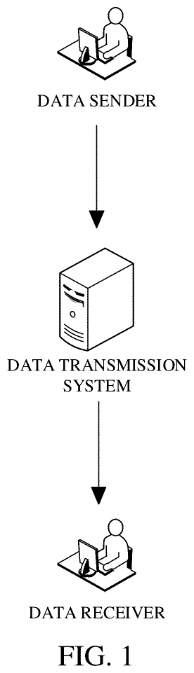

FIG. 1 is a structural arrangement diagram of a data transmission system. As illustrated in FIG. 1, a first end of the system is connected to a data sender, and a second end of the system is connected to a data receiver.

The data sender is a role that sends the original data to the data transmission system to compress for the purpose of sending the original data to the data receiver.

The data transmission system is configured to receive the original data from the data sender, and split the original data into multiple data splits with the same size for data transmission, thereby sending the original data from the data sender to the data receiver.

The data receiver is a role that receives the multiple data splits from the data transmission system and restores the multiple data splits to obtain the original data.

In the process of data transmission by the above system, since the original data is just split into multiple data splits with the same size, the multiple data splits show no regularity in data content, and thus a method for data compression is irregular for each of the multiple data splits. In this case, a large amount of time may be spent to match methods for data compression in the process of compressing a large number of data splits. It may be seen that the above process does not make enough improvement on the speed of data transmission.

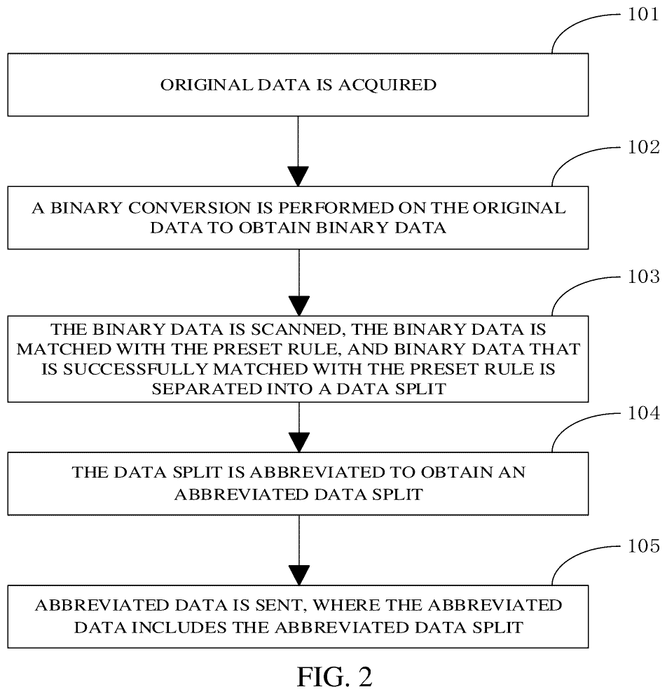

Therefore, embodiments of the disclosure provide a method for data compression based on a preset rule. Reference is made to FIG. 2, which is a flowchart of a method for data compression based on a preset rule provided in an embodiment of the disclosure. As illustrated in FIG. 2, the method includes the following operations.

At 101, original data is acquired.

The original data may be in a format of numerical value, text, image, sound, etc.

At 102, a binary conversion is performed on the original data to obtain binary data.

In specific embodiments, the binary conversion is performed on the original data as follows. The binary conversion may be performed on different types of original data through program codes such as JavaScript, C#, and the like.

The binary data includes two binary symbols, namely 0 and 1.

Exemplarily, the original data is a numerical value 8. A binary conversion is performed on the numerical value 8 to obtain a binary data 1000.

At 103, the binary data is scanned, the binary data is matched with the preset rule, and binary data that is successfully matched with the preset rule is separated into a data split.

The preset rule means that data has a certain degree of regularity. There can be more than one preset rule. In specific embodiments, the binary data that is successfully matched with the preset rule is separated into a data split as follows. Binary data sections that are successfully matched with different preset rules may be separated into different data splits, thereby completing the separation of the binary data.

Exemplarily, there are preset rule 1 and preset rule 2, and the binary data is scanned. If binary data section 1 of the binary data is successfully matched with the preset rule 1 and binary data section 2 of the binary data is successfully matched with the preset rule 2, the binary data section 1 is determined as data split 1 and the binary data section 2 is determined as data split 2, thereby completing the separation of the binary data.

For another example, there is a binary data 00001111 and the preset rule is that the data split only includes identical binary symbols, which means the data split only includes 0 or 1. After the binary data 00001111 is matched with the preset rule, the binary data 00001111 will be separated into two data splits 0000 and 1111 since binary data section 0000 and binary data section 1111 both include identical binary symbols.

At 104, the data split is abbreviated to obtain an abbreviated data split.

In specific embodiments, the data split is abbreviated as follows. The data split may be abbreviated according to the content of the data split. Alternatively, each data split may be abbreviated by abbreviating a data pattern according to the content of the data pattern in the data split. The data pattern is a pattern that may include n-bit data, and the n-bit data included in a data pattern is different from another data patterns for the purpose of representing different data contents.

Exemplarily, there are two data splits 0000 and 1111. Since the two data splits are different in content, the data split 0000 may be abbreviated into 0 and the data split 1111 may be abbreviated into 1. In this way, the abbreviation of the two data splits is completed. For another example, each data pattern is assumed to include 2-bit data. If each data pattern is abbreviated according to the content of each data pattern in the data split, data pattern 00 may be abbreviated into 0 and data pattern 11 may be abbreviated into 1. In this way, the data split 0000 is abbreviated into 00 and the data split 1111 is abbreviated into 11, thereby completing the abbreviation of the two data splits.

For another example, the preset rule is assumed to be that the data split only includes identical binary symbols, and the data split may also be abbreviated as follows. The number of the identical binary symbols is marked to obtain a marked number, where the marked number is in a binary form. Then, the marked number and the content of the identical binary symbols are arranged in a preset arrangement manner. For example, there is a data split 00000000, which consists of 8 identical binary symbols 0. The binary form of 8 is 1000, and 1000 is marked to obtain (1000). If the preset arrangement manner is that the content of the identical binary symbols is arranged in the next bit of the marked number, the data split 00000000 will be abbreviated into (1000)0.

It should be noted that the above embodiments only serve as examples of abbreviating the data split. In specific embodiments, the data split may be abbreviated through other manners, which will not be limited herein.

At 105, abbreviated data is sent, where the abbreviated data includes the abbreviated data split.

There may be one or more abbreviated data splits. Therefore, in specific embodiments, the abbreviated data may consist of one abbreviated data split, or may consist of multiple data splits that are spliced in order.

In specific embodiment, the abbreviated data is sent as follows. The abbreviated data may be sent after all the data splits are abbreviated. Alternatively, during the process of abbreviating the data splits, part of the data splits that have been abbreviated may be sent first while other remaining data splits are being abbreviated. That is, abbreviating the data splits and sending the abbreviated data can be performed synchronously. Once a data split is abbreviated, it can be sent to the data receiver.

Exemplarily, there are data split 1 and data split 2, in specific embodiments, the data split 1 and the data split 2 are abbreviated first, and then the abbreviated data split 1 and the abbreviated data split 2 are sent. Alternatively, the data split 1 is abbreviated into the abbreviated data split 1, and then the abbreviated data split 1 is sent while the data split 2 is being abbreviated.

The following will introduce devices involved in embodiments of the disclosure with reference to the accompanying drawings.

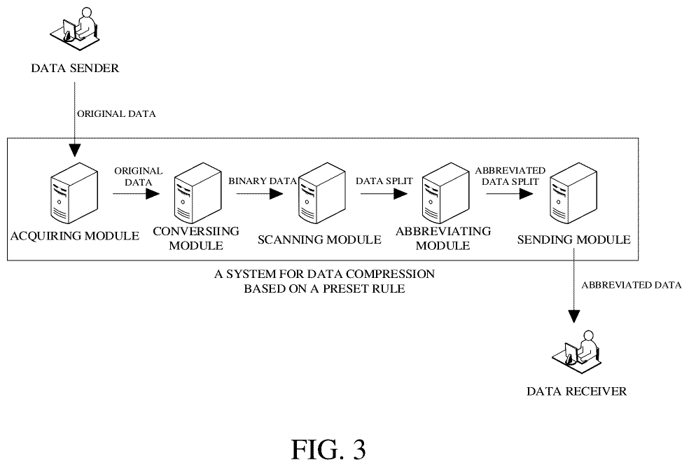

Reference is made to FIG. 3, which is an arrangement diagram of a system for data compression based on a preset rule applied by an embodiment of the disclosure. As illustrated in FIG. 3, the system includes an acquiring module, a conversing module, a scanning module, an abbreviating module, and a sending module. A first end of the system is connected to the data sender and a second end is connected to the data receiver. The functions of different modules may be realized by different servers or the functions of multiple modules may be realized by one server. Servers realizing the functions of different modules are communicatively connected to each other. The server may be an independent server or a cloud server that provides basic cloud computing services such as cloud services, a cloud database, cloud computing, cloud functions, cloud storage, network services, cloud communications, middleware services, domain name services, security services, a content delivery network (CDN), and a big data and artificial intelligence platform.

The data sender is a role that sends the original data to the acquiring module of the data transmission system based on a preset rule, for the purpose of sending the original data to the data receiver.

The acquiring module is configured to receive the original data from the data sender and send the original data to the conversing module.

The conversing module is configured to, after receiving the original data from the acquiring module, perform a binary conversion on the original data to obtain binary data, and send the binary data to the scanning module.

The scanning module is configured to, after receiving the binary data from the conversing module, scan the binary data, match the binary data with the preset rule, separate the binary data that is successfully matched with the preset rule into data splits, and send the data splits to the abbreviating module.

The abbreviating module is configured to, after receiving the data splits from the scanning module, abbreviate the data splits to obtain abbreviated data splits, and send the abbreviated data splits to the sending module.

The sending module is configured to, after receiving the abbreviated data splits from the abbreviating module, splice the abbreviated data splits to obtain abbreviated data, and send the abbreviated data including the abbreviated data splits to the data receiver.

The data receiver is a role that receives the abbreviated data from the system for data compression based on a preset rule, and restore the abbreviated data to obtain the original data sent by the data sender.

Exemplarily, a binary conversion is performed on original data to obtain a binary data 00000000001111111111. The preset rule is that the data split only includes identical binary symbols, that is, the data split only includes 0 or 1. When the binary data 00000000001111111111 is matched with the preset rule, the binary data 00000000001111111111 is separated into data split 0000000000 and data split 1111111111, since the binary data section 0000000000 and the binary data section 1111111111 both include identical binary symbols. An abbreviation manner for data split that is matched with the preset rule is assumed to be as follows. The number of the identical binary symbols is marked to obtain a marked number, where the marked number is in a binary form, and then the marked number and the content of the identical binary symbols are arranged in a preset arrangement manner. It can be seen that both the data split 0000000000 and the data split 1111111111 include 10 identical binary symbols, and the binary form of 10 is 1010. Therefore, the data split 0000000000 is abbreviated into abbreviated data split 1 and the data split 1111111111 is abbreviated into abbreviated data split 2. The abbreviated data split 1 is (1010)0, and the abbreviated data split 2 is (1010)1. The two abbreviated data splits are spliced to obtain an abbreviated data (1010)0(1010)1, and then the abbreviated data (1010)0(1010)1 is sent. It is obvious that the data volume of the abbreviated data has been greatly reduced compared to the binary data 00000000001111111111, which is beneficial for improving the speed of data transmission.

In the embodiment of the disclosure, the original data is acquired; the binary conversion on the original data is performed to obtain the binary data; the binary data is scanned, the binary data is matched with the preset rule, and binary data that is successfully matched with the preset rule is separated into the data split; the data split is abbreviated to obtain the abbreviated data split; and the abbreviated data is sent, where the abbreviated data includes the abbreviated data split. In the method for data compression provided in embodiments of the disclosure, the binary data is matched with the preset rule, the binary data that is successfully matched with the preset rule is separated into the data split, and then the data split is abbreviated. Since the binary data is matched with the preset rule, the binary data may be separated and abbreviated with a certain regularity, which may improve the efficiency of data transmission.

In a possible embodiment, the preset rule is that a data split consists of identical binary symbols and the number of the identical binary symbols is greater than a preset number. The binary data is matched with the preset rule and binary data that is successfully matched with the preset rule is separated into the data split as follows.

A first binary data section is acquired, where the first binary data section consists of multiple identical binary symbols, and a binary symbol is 0 or 1. When the number of identical binary symbols in the first binary data section is greater than the preset number, the first binary data section is determined to be successfully matched with the preset rule. The first binary data section is determined as the data split.

The preset number may be 5 or other values.

The preset rule is that a data split consists of identical binary symbols and the number of the identical binary symbols is greater than a preset number. In this way, data content of the data split may be unitary and highly repetitive, the complexity of the data content of the data split may be reduced, and thus the complexity of subsequent abbreviation of the data split may be reduced.

Exemplarily, the preset number is 5, and the first binary data section acquired is 00000000. That is, the number of identical binary symbols in the first binary data section is 8, which is greater than the preset number. Then, the first binary data section is determined to be successfully matched with the preset rule. Therefore, the first binary data section 00000000 is determined as the data split.

In the embodiment of the disclosure, when the preset rule is that a data split consists of identical binary symbols and the number of the identical binary symbols is greater than a preset number, a first binary data section consisting of multiple identical binary symbols is acquired. When the number of identical binary symbols in the first binary data section is greater than the preset number, the first binary data section is determined to be successfully matched with the preset rule, and the first binary data section is determined as the data split. In this way, binary data that is successfully matched with the preset rule is separated into a data split. By ensuring that the data content of the data split is unitary and highly repetitive, the complexity of subsequent abbreviation of the data split may be reduced, which is beneficial for improving the speed of data transmission.

In a possible embodiment, the data split is abbreviated as follows. The content and the number of the identical binary symbols in the data split are acquired. The number of the identical binary symbols is marked to obtain a marked number, where the marked number is in a binary form. The abbreviated data split is determined, where the abbreviated data split includes the marked number and the content of the identical binary symbols that are arranged in a preset arrangement manner.

The content of the identical binary symbols is 0 or 1.

The number of the identical binary symbols is marked. In specific embodiments, the number of the identical binary symbols may be marked with a mark () or other marks.

The marked number and the content of the identical binary symbols are arranged in a preset arrangement manner. In specific embodiments, the marked number may be arranged in the previous bit of the content of the identical binary symbols, or may be arranged in the next bit of the content of the identical binary symbols.

For example, the number of the identical binary symbols is marked with the mark () and the marked number is arranged in the previous bit of the content of the identical binary symbols. In this case, for a data split 00000000, the acquired content of the identical binary symbols is 0 and the acquired number of the identical binary symbols is 8. The binary form of 8 is 1000. The number of the identical binary symbols is marked to obtain a marked number (1000), and the abbreviated data split is determined as (1000)0. Therefore, the data split 00000000 is abbreviated. Likewise, if the marked number is arranged in the next bit of the content of the identical binary symbols, the abbreviated data split is 0(1000).

In the embodiment of the disclosure, when the preset rule is that a data split consists of identical binary symbols and the number of the identical binary symbols is greater than a preset number, the content and the number of the identical binary symbols in the data split are acquired, and the data split is abbreviated to include the marked number and the content of the identical binary symbols that are arranged in a preset arrangement manner. In this way, the data transmission volume is greatly reduced, thereby improving the speed of data transmission.

In a possible embodiment, the above method further includes the following. A data dictionary corresponding to the data split is generated, where the data dictionary represents a marking manner for the number of the identical binary symbols in the data split, and represents the preset arrangement manner for the marked number and the content of the identical binary symbols. The data dictionary is sent, or an indicator of the data dictionary is sent, where the indicator of the data dictionary represents the data dictionary corresponding to the data split.

The data dictionary is sent, which means that the data sender directly sends the data dictionary to the data receiver when the data sender sends the abbreviated data, where the data dictionary corresponds to the data split. The indicator of the data dictionary is sent, which means that the data sender only sends the indicator representing the data dictionary corresponding to the data split when the data sender sends the abbreviated data, where the indicator of the data dictionary corresponds to the data split.

In specific embodiments, the data transmission volume of sending the indicator of the data dictionary is smaller than the data transmission volume of directly sending the data dictionary. If the data receiver locally stores the data dictionary, the speed of data transmission may be further improved by sending the indicator of the data dictionary.

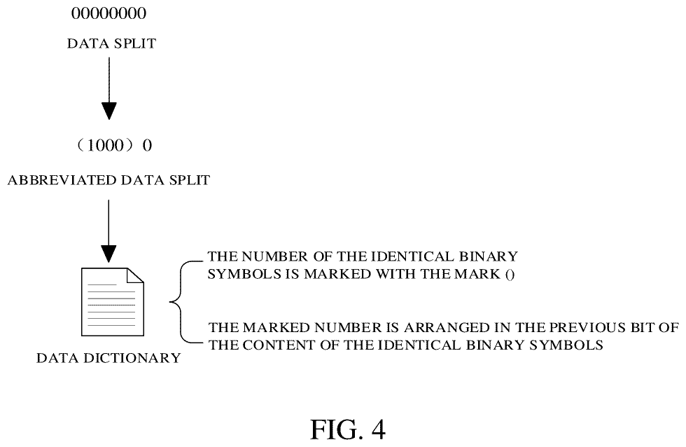

Exemplarily, reference is made to FIG. 4, which is a schematic diagram of a method for data compression based on a preset rule provided in an embodiment of the disclosure. As illustrated in FIG. 4, there is a data split 00000000. If the data split 00000000 is abbreviated into (1000)0, the data dictionary corresponding to the data split is generated, where the data dictionary represents an abbreviation manner of the data split. That is, the number of the identical binary symbols is marked with the mark () and the marked number is arranged in the previous bit of the content of the identical binary symbols.

In the embodiment of the disclosure, the data dictionary is generated according to the abbreviation manner of the data split, where the data dictionary represents the marking manner for the number of the identical binary symbols in the data split, and represents the preset arrangement manner for the marked number and the content of the identical binary symbols. The data dictionary is sent, or the indicator representing the data dictionary corresponding to the data split is sent. In this way, the data receiver is informed that a restoration method that is included in the abbreviated data and corresponding to the abbreviated data split, and thus the data receiver may restore the abbreviated data according to the data dictionary to obtain the original data.

In a possible embodiment, before sending the abbreviated data, the method further includes the following. Other data in the binary data other than the data split is acquired. A length of binary data occupied by a same repetition pattern in the other data is obtained. A repetition pattern occupying the longest length of binary data is determined as a target pattern.

The target pattern is abbreviated to obtain an abbreviated pattern data. The abbreviated data is sent by sending the abbreviated data, where the abbreviated data includes the abbreviated data split and the abbreviated pattern data.

The repetition pattern is one of the above data patterns.

Exemplarily, a data pattern is assumed to include 2-bit data. If other data in the binary data other than the data split obtained as 10101010000101, then other data includes three kinds of data patterns, which are 10, 00, and 01. A length of binary data occupied by data pattern 10 is 8, a length of binary data occupied by data pattern 00 is 2, and a length of binary data occupied by data pattern 01 is 4. Therefore, a repetition pattern 10 occupying the longest length of binary data is determined as a target pattern. The target pattern 10 of 10101010000101 is abbreviated to obtain an abbreviated pattern data corresponding to the target pattern. If an abbreviation manner for the target pattern is to abbreviate the target pattern into 0, the abbreviated pattern data is 0. That is, 10101010000101 is abbreviated into 0000000101.

In the embodiment of the disclosure, before sending the abbreviated data, other data in the binary data other than the data split is acquired. The repetition pattern occupying the longest length of binary data is determined as the target pattern. The target pattern is abbreviated to obtain the abbreviated pattern data, as such the abbreviated data includes the abbreviated data split and the abbreviated pattern data. By abbreviating the repetition pattern occupying the longest length of binary data, the data transmission volume is greatly reduced, and thus the speed of data transmission is improved.

In a possible embodiment, the above method further includes the following. A secondary target pattern is determined according to a length of binary data occupied by a same repetition pattern, where the secondary target pattern is a repetition pattern occupying a length of binary data second only to the target pattern. The secondary target pattern is abbreviated to obtain a secondary abbreviated pattern data. The abbreviated data is sent as follows. The secondary abbreviated data is sent, where the secondary abbreviated data includes the abbreviated data split, the abbreviated pattern data, and the secondary abbreviated pattern data.

Exemplarily, a data pattern is assumed to include 2-bit data. If other data in the binary data other than the data split is 10101010000101, as can be seen from the above embodiment, the secondary target pattern occupying a length of binary data second only to the target pattern 10 is 01. Therefore, the secondary target pattern is abbreviated to obtain the secondary abbreviated pattern data. If the abbreviation manner for the secondary target pattern is to abbreviate the secondary target pattern into 1, the secondary abbreviated pattern data is 1. In this way, after the target pattern 10 is abbreviated into 0 and the secondary target pattern 01 is abbreviated into 1, 10101010000101 is abbreviated into 00000011.

In the embodiment of the disclosure, after the target pattern occupying the longest length of binary data is abbreviated, the secondary target pattern occupying a length of binary data second only to the target pattern is abbreviated. By abbreviating the target pattern occupying the longest length of binary data and the secondary target pattern occupying a length of binary data second only to the target pattern, the data transmission volume is further reduced, and thus the speed of data transmission is greatly improved.

In a possible embodiment, the above method further includes the following. A data dictionary corresponding to other data is generated, where the data dictionary represents a corresponding relationship between the target pattern and the abbreviated pattern data. The data dictionary is sent, or an indicator of the data dictionary is sent, where the indicator of the data dictionary represents the data dictionary corresponding to other data.

The data dictionary is sent, which means that the data sender directly sends the data dictionary to the data receiver when the data sender sends the abbreviated data, where the data dictionary corresponds to other data. The indicator of the data dictionary is sent, which means that the data sender only sends the indicator representing the data dictionary corresponding to other data when the data sender sends the abbreviated data, where the indicator of the data dictionary corresponds to other data.

In specific embodiments, the data transmission volume of sending the indicator of the data dictionary is smaller than the data transmission volume of directly sending the data dictionary. If the data receiver locally stores the data dictionary, the speed of data transmission may be further improved by sending the indicator of the data dictionary.

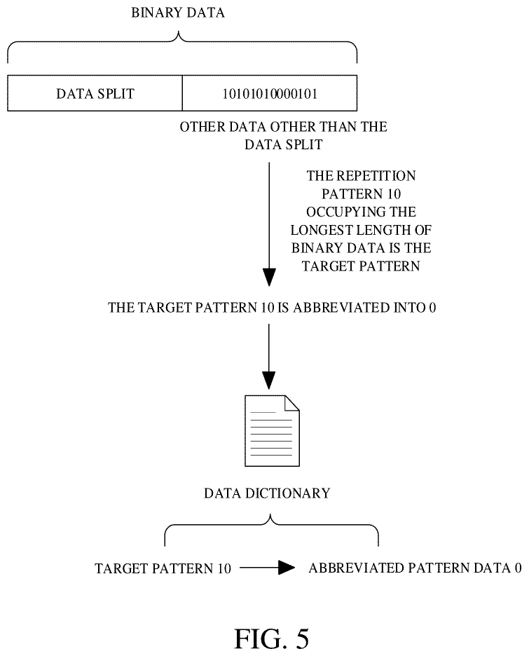

Exemplarily, reference is made to FIG. 5, which is a schematic diagram of another method for data compression based on a preset rule provided in an embodiment of the disclosure.

As illustrated in FIG. 5, other data other than the data split is 10101010000101. As can be seen in the above embodiment, the repetition pattern 10 occupying the longest length of binary data is the target pattern. The target pattern 10 can be abbreviated into 0, that is, the abbreviated pattern data is 0. Therefore, the data dictionary represents the corresponding relationship between the target pattern 10 and the abbreviated pattern data 0.

In the embodiment of the disclosure, the data dictionary is generated according to the corresponding relationship between the target pattern and the abbreviated pattern data. The data dictionary is sent, or the indicator representing the data dictionary corresponding to other data is sent. In this way, the data receiver is informed that the abbreviated pattern data and a restoration method corresponding to the abbreviated data pattern that are included in the abbreviated data, and thus the data receiver may restore the abbreviated data according to the data dictionary to obtain the original data.

In a possible embodiment, the above method further includes the following. A first duration corresponding to abbreviating the data split is acquired. An estimated second duration corresponding to sending the abbreviated data split is acquired. The data split is split into multiple data sub-splits when a difference between the first duration and the second duration is greater than a preset duration. The data split is abbreviated by abbreviating all or some of the multiple data sub-splits.

In specific embodiments, the first duration corresponding to abbreviating the data split can be calculated according to a historic average abbreviating speed, and the estimated second duration corresponding to sending the abbreviated data split can be calculated according to a historic average data transmission speed.

The preset duration may be 200 ms or others.

The data split is split into multiple data sub-splits. In specific embodiments, the data split may be split according to the length of the data split. After the data split is split into multiple data sub-splits, the multiple data sub-splits are abbreviated into multiple abbreviated data sub-splits. In this case, the difference between an abbreviating duration corresponding to each data sub-split and a sending duration corresponding to each abbreviated data sub-split is less than or equal to the preset duration.

The data split is split into multiple data sub-splits when a difference between the first duration and the second duration is greater than the preset duration. In this way, the existence of an excessively long data split may be avoided, and a large amount of time needed to abbreviate the excessively long data split may be saved. Therefore, the data transmission channel may not be vacant for a long time, and the time utilization ratio during the data transmission process may not be reduced.

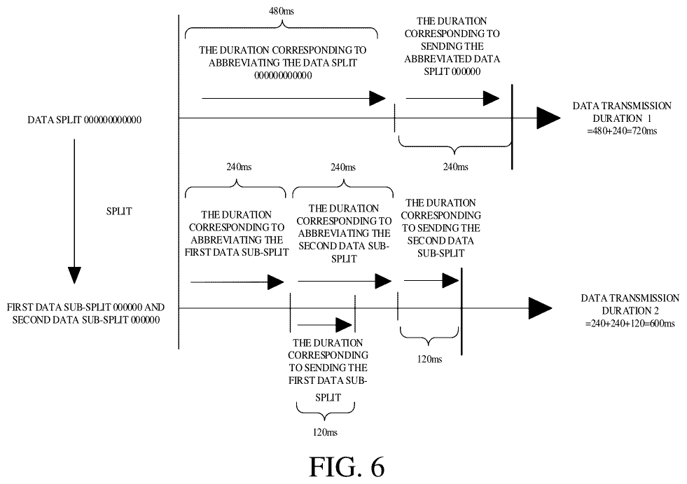

Exemplarily, it is assumed that abbreviating the data split and sending the abbreviated data can be processed synchronously, and the data split can be sent to the data receiver once the data split is abbreviated. It is assumed that the preset duration is 200 ms, and there is a data split 000000000000, where the corresponding abbreviated data split of the data split is 00000000. It is assumed that the time spent in abbreviating one bit is 40 ms and the time spent in sending one bit each is 40 ms. Since the data split 000000000000 has 12 bits, a first duration corresponding to abbreviating the data split is acquired as 480 ms, and an estimated second duration corresponding to sending the data split is acquired as 240 ms. It can be seen that the difference between the first duration and the second duration is greater than the preset duration. Therefore, the data split 000000000000 is equally split into a first data sub-split 000000 and a second data sub-split 000000. It is assumed that an abbreviated data sub-split corresponding to the first data sub-split is a first abbreviated data sub-split 000, and an abbreviated data sub-split corresponding to the second data sub-split is a second abbreviated data sub-split 000. It can be calculated that the first duration corresponding to abbreviating each data sub-split is 240 ms, and the second time duration corresponding to sending each abbreviated data sub-split is 120 ms. Reference is made to FIG. 6, which is a schematic diagram of another method for data compression based on a preset rule provided in an embodiment of the disclosure. As illustrated in FIG. 6, if the data split 000000000000 is directly abbreviated and sent, a data transmission duration 1=the duration corresponding to abbreviating the data split 000000000000+the duration corresponding to sending the abbreviated data split 000000=480+240=720 ms. However, if the data split 000000000000 is equally split into the first data sub-split 000000 and the second data sub-split 000000 for abbreviating and sending, since the first abbreviated data sub-split 000 can be sent while the second data sub-split 000000 is being abbreviated, a data transmission duration 2=the duration corresponding to abbreviating the first data sub-split+the duration corresponding to abbreviating the second data sub-split+the duration corresponding to sending the second data sub-split=240+240+120=600 ms. It is obvious that the data transmission duration 2 is less than the data transmission duration 1. It can be seen that, by adopting the method of the embodiment, a data split being excessively long may be avoided, and the time utilization ratio during the data transmission process may not be reduced, and thus the speed of data transmission is improved.

In the embodiment of the disclosure, the data split is split into multiple data sub-splits when the difference between the first duration corresponding to abbreviating the data split and the estimated second duration corresponding to sending the abbreviated data split is greater than a preset duration, and then all or some of the multiple data sub-splits are abbreviated. By adopting the method for data compression provided in the embodiment of the disclosure, the difference between the duration of abbreviating the data split and the estimated duration of sending the abbreviated data split may fall in a rational range. In this way, the speed of data transmission may be improved by improving the time utilization ratio during the data transmission process.

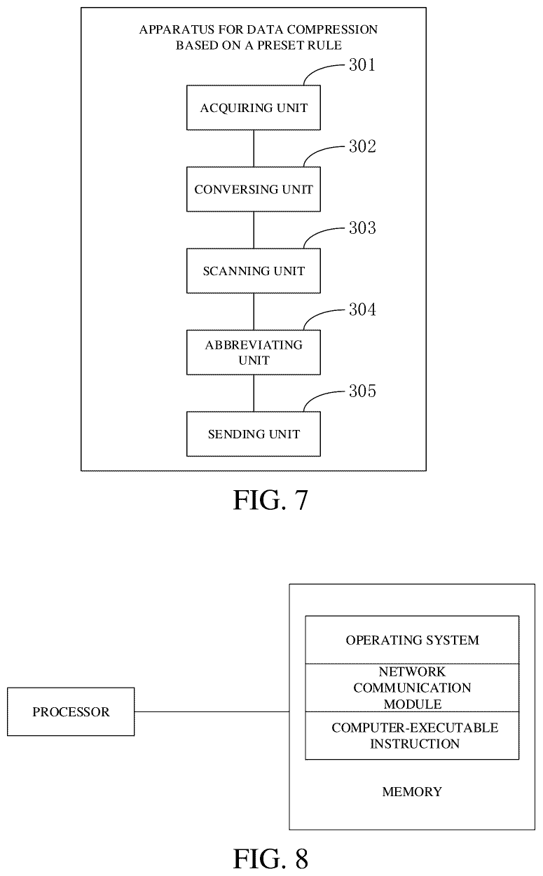

Consistent with the embodiment of the FIG. 2, reference is made to FIG. 7, which is a structural diagram of an apparatus for data compression based on a preset rule provided in an embodiment of the disclosure. As illustrated in FIG. 7, the apparatus for data compression based on a preset rule includes an acquiring unit 301, a conversing unit 302, a scanning unit 303, an abbreviating unit 304, and a sending unit 305.

The acquiring unit 301 is configured to acquire original data. The conversing unit 302 is configured to perform a binary conversion on the original data to obtain binary data. The scanning unit 303 is configured to scan the binary data, match the binary data with the preset rule, and separate the binary data that is successfully matched with the preset rule into a data split. The abbreviating unit 304 is configured to abbreviate the data split to obtain an abbreviated data split. The sending unit 305 is configured to send abbreviated data, wherein the abbreviated data comprises the abbreviated data split.

In the apparatus provided in the embodiment of the disclosure, the acquiring unit 301 is configured to acquire the original data; the conversing unit 302 is configured to perform a binary conversion on the original data to obtain the binary data; the scanning unit 303 is configured to scan the binary data, match the binary data with the preset rule, and separate the binary data that is successfully matched with the preset rule into a data split; the abbreviating unit 304 is configured to abbreviate the data split to obtain the abbreviated data split; and the sending unit 305 is configured to send the abbreviated data, where the abbreviated data includes the abbreviated data split. By adopting the apparatus for data compression provided in embodiments of the disclosure, the binary data is matched with the preset rule, the binary data that is successfully matched with the preset rule is separated into the data split, and then the data split is abbreviated. Since the binary data is matched with the preset rule, the binary data may be separated and abbreviated with a certain regularity, which may improve the efficiency of data transmission.

Specifically, in the embodiment of the disclosure, functional units of the apparatus for data compression based on a preset rule may be divided according to the above method. For example, functional units may be divided into different functional units according to different functions, or two or more functions may be integrated in one processing unit. The integrated unit may be implemented in a form of hardware, or may be implemented in a form of a software functional unit. It should be noted that, division of the units in the embodiment of the disclosure is an example, and is merely logical function division. In actual implementation, another division manner may be used.

Consistent with the above embodiment of FIG. 2, an electronic device is provided in the embodiment of the disclosure. Reference is made to FIG. 8, which is a schematic structural diagram of a server for hardware operating environment of an electronic device provided in an embodiment of the disclosure. As illustrated in FIG. 8, the electronic device includes a processor, a memory, and a computer-executable instruction that is stored in the memory and executable on the processor. The computer-executable instruction, when executed, causes the electronic device to execute instructions including any steps of the method for data compression based on a preset rule.

The processor is a central processing unit (CPU).

Optionally, the memory can be a high-speed random-access memory (RAM), or can be a non-transitory memory. For example, the memory is a magnetic disk storage.

Those of ordinary skills in the art may understand that the structure of the server illustrated in FIG. 8 does not constitute any limitation on the server. The server may further include components more or fewer than those shown in the figure, or in the server, some components are combined, or the components are disposed differently.

As illustrated in FIG. 8, the memory may include an operating system, a network communication module, and a computer-executable instruction of the method for data compression based on a preset rule. The operating system is configured to manage and control server hardware and software resources, supporting the execution of the computer-executable instruction. The network communication module is configured to realize the communication between various components inside the memory, as well as communication between other hardware and software inside the server. The communication may use any communication standard or protocol, including but not limited to global system of mobile communication (GSM), general packet radio service (GPRS), code division multiple access 2000 (CDMA2000), wideband code division multiple access (WCDMA), time division synchronous code division multiple access (TD-SCDMA), and the like.

In the server illustrated in FIG. 8, the processor is configured to execute the personnel-managed computer-executable instruction stored in the memory, in order to realize the following. The original data is acquired. The binary conversion on the original data is performed to obtain the binary data. The binary data is scanned, the binary data is matched with the preset rule, and binary data that is successfully matched with the preset rule is separated into the data split. The data split is abbreviated to obtain the abbreviated data split. The abbreviated data is sent, where the abbreviated data includes the abbreviated data split.

Specific embodiments of the servers involved in the disclosure can be found in various embodiments of the method for data compression based on a preset rule described above, which will not be repeated herein.

Embodiments of the disclosure provide a non-transitory computer-readable storage medium. The non-transitory computer-readable storage medium stores a computer instruction, and the computer instruction, when executed on a communication device, causes the communication device to execute the following. The original data is acquired. The binary conversion on the original data is performed to obtain the binary data. The binary data is scanned, the binary data is matched with the preset rule, and binary data that is successfully matched with the preset rule is separated into the data split. The data split is abbreviated to obtain the abbreviated data split. The abbreviated data is sent, where the abbreviated data includes the abbreviated data split. The above computer includes the electronic device.

The electronic device may be a mobile phone, a tablet, a personal digital assistant, a wearable device, etc.

The non-transitory computer-readable storage medium may be an internal storage unit of the electronic device in the above embodiment, for example, a hard disk or a memory of the electronic device. The non-transitory computer-readable storage medium may also be an external storage device of the electronic device, such as a plug-in hard drive, a smart media card (SMC), a secure digital (SD) card, a flash card, etc. Furthermore, the non-transitory computer-readable storage medium may include both an internal storage unit of the electronic device and an external storage device. The non-transitory computer-readable storage medium is used to store computer-executable instructions and other computer-executable instructions and data required by the electronic device. The non-transitory computer-readable storage medium can also be used to temporarily store data that has been output or will be output.

The specific embodiment of the non-transitory computer-readable storage medium involved in the disclosure can be referred to the embodiments of the method for data compression based on a preset rule described above, which will not be repeated herein.

Embodiments of the disclosure provide a computer program product. The computer program product includes a computer program, which is operable to cause a computer to perform some or all of the steps in any method for data compression based on a preset rule in the above method embodiments. The computer program product may be a software installation package.

It should be noted that, for any embodiments of the above method for data compression based on a preset rule, the steps are described as a series of action combinations for ease of description, but those of ordinary skills in the art should know that, the present invention is not limited by a sequence of described actions. Secondly, those of ordinary skills in the art should also know that, the embodiments described in the specification are preferred embodiments, and the involved actions are not necessarily needed by the embodiments of the present invention.

The embodiments of the disclosure are described in details. The principles and embodiments of the disclosure, which is a method and an apparatus for data compression based on a preset rule, a device, and a medium, are described through specific examples. The description of the above embodiments is for the purposes to understand the method and core ideas of the present disclosure. Those of ordinary skills in the art may perform modification on the specific embodiments and the scope of application based on the idea of the disclosure, which is a method and an apparatus for data compression based on a preset rule, a device, and a medium. In summary, content of the present specification should not be construed as limiting the present disclosure.

The present disclosure is described with reference to the flowcharts and/or block diagrams of the method, the hardware products, and the computer program product according to the embodiments of the present disclosure. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of any other programmable data processing device to generate a machine, so that the instructions executed by a computer or a processor of any other programmable data processing device generate an apparatus for implementing a specific function in one or more processes in the flowcharts and/or in one or more blocks in the block diagrams.

These computer program instructions may also be stored in a computer-readable memory that can instruct the computer or any other programmable data processing device to work in a specific manner, so that the instructions stored in the computer-readable memory generate an artifact that includes an instruction apparatus. The instruction apparatus implements a specific function in one or more processes in the flowcharts and/or in one or more blocks in the block diagrams. The memory may include a flash drive, a read only memory (ROM), a random access memory (RAM), a magnetic disk, an optical disk, etc.

Although the disclosure is described with reference to the embodiments, in a process of implementing the disclosure that claims protection, those of ordinary skills in the art may understand and implement another variation of the disclosed embodiments by viewing the accompanying drawings, disclosed content, and the accompanying claims. In the claims, “comprising” does not exclude another component or another step, and “a” or “one” does not exclude a case of multiple. A single processor or another unit may implement several functions enumerated in the claims. The fact that some measures are recorded in mutually different dependent claims does not indicate that a combination of these measures cannot bring better effects.

It may be understood by those of ordinary skills in the art that some or all of the steps of the various methods of the embodiments of the method for data compression based on a preset rule described above may be accomplished by means of a program to instruct associated hardware. The program may be stored in a computer-readable memory, which may include a flash memory, a ROM, a RAM, a magnetic disk, an optical disk, etc.

Obviously, those of ordinary skills in the art can make various modifications and variations to the disclosure, which is a method and an apparatus for data compression based on a preset rule, a device, and a medium, without departing from the spirit and scope of the disclosure. The disclosure is intended to cover these modifications and variations of the disclosure provided that they fall within the scope of protection defined by the following claims and their equivalent technologies.

What is claimed is:

1. A method for data compression based on a preset rule, comprising:
acquiring original data;
performing a binary conversion on the original data to obtain binary data;
scanning the binary data, matching the binary data with the preset rule, and separating binary data that is successfully matched with the preset rule into a data split;
abbreviating the data split to obtain an abbreviated data split; and
sending abbreviated data, wherein the abbreviated data comprises the abbreviated data split.

2. The method of claim 1, wherein the preset rule is that a data split consists of identical binary symbols and a number of the identical binary symbols is greater than a preset number, and wherein matching the binary data with the preset rule, and separating the binary data that is successfully matched with the preset rule into the data split comprises:
acquiring a first binary data section, wherein the first binary data section consists of a plurality of identical binary symbols, and a binary symbol is 0 or 1;
determining that the first binary data section is successfully matched with the preset rule in response to a number of the identical binary symbols in the first binary data section being greater than the preset number; and
determining the first binary data section as the data split.

3. The method of claim 2, wherein abbreviating the data split comprises:
acquiring a content and the number of the identical binary symbols in the data split;
marking the number of the identical binary symbols to obtain a marked number, wherein the marked number is in a binary form; and
determining the abbreviated data split, wherein the abbreviated data split comprises the marked number and the content of the identical binary symbols that are arranged in a preset arrangement manner.

4. The method of claim 3, further comprising:
generating a data dictionary corresponding to the data split, wherein the data dictionary represents a marking manner for the number of the identical binary symbols in the data split, and represents the preset arrangement manner for the marked number and the content of the identical binary symbols; and
sending the data dictionary; or sending an indicator of the data dictionary, wherein the indicator of the data dictionary represents the data dictionary corresponding to the data split.

5. The method of claim 2, wherein before sending the abbreviated data, the method further comprises:
acquiring other data in the binary data other than the data split;
obtaining a length of binary data occupied by a same repetition pattern in the other data;
determining a repetition pattern occupying the longest length of binary data as a target pattern; and
abbreviating the target pattern to obtain an abbreviated pattern data;
wherein sending the abbreviated data comprises:
sending the abbreviated data, wherein the abbreviated data comprises the abbreviated data split and the abbreviated pattern data.

6. The method of claim 5, further comprising:
generating a data dictionary corresponding to the other data, wherein the data dictionary represents a corresponding relationship between the target pattern and the abbreviated pattern data; and
sending the data dictionary; or sending an indicator of the data dictionary, wherein the indicator of data dictionary represents the data dictionary corresponding to the other data.

7. The method of claim 5, further comprising:
determining a secondary target pattern according to a length of binary data occupied by a same repetition pattern, wherein the secondary target pattern is a repetition pattern occupying a length of binary data second only to the target pattern; and
abbreviating the secondary target pattern to obtain a secondary abbreviated pattern data;
wherein sending the abbreviated data comprises:
sending the secondary abbreviated data, wherein the secondary abbreviated data comprises the abbreviated data split, the abbreviated pattern data, and the secondary abbreviated pattern data.

8. The method of claim 2, further comprising:
acquiring a first duration corresponding to abbreviating the data split;
acquiring an estimated second duration corresponding to sending the abbreviated data split; and
splitting the data split into a plurality of data sub-splits in response to a difference between the first duration and the second duration being greater than a preset duration;
wherein abbreviating the data split comprises:
abbreviating all or some of the plurality of data sub-splits.

9. An electronic device, comprising a processor, a memory, and a computer-executable instruction that is stored in the memory and executable on the processor, wherein the computer-executable instruction, when executed, causes the electronic device to execute:
acquiring original data;
performing a binary conversion on the original data to obtain binary data;
scanning the binary data, matching the binary data with the preset rule, and separating binary data that is successfully matched with the preset rule into a data split;
abbreviating the data split to obtain an abbreviated data split; and
sending abbreviated data, wherein the abbreviated data comprises the abbreviated data split.

10. The electronic device of claim 9, wherein the preset rule is that a data split consists of identical binary symbols and a number of the identical binary symbols is greater than a preset number, and wherein in terms of matching the binary data with the preset rule, and separating the binary data that is successfully matched with the preset rule into the data split, the computer-executable instruction causes the electronic device to execute:
acquiring a first binary data section, wherein the first binary data section consists of a plurality of identical binary symbols, and a binary symbol is 0 or 1;
determining that the first binary data section is successfully matched with the preset rule in response to a number of the identical binary symbols in the first binary data section being greater than the preset number; and
determining the first binary data section as the data split.

11. The electronic device of claim 10, wherein in terms of abbreviating the data split, the computer-executable instruction causes the electronic device to execute:
acquiring a content and the number of the identical binary symbols in the data split;
marking the number of the identical binary symbols to obtain a marked number, wherein the marked number is in a binary form; and
determining the abbreviated data split, wherein the abbreviated data split comprises the marked number and the content of the identical binary symbols that are arranged in a preset arrangement manner.

12. The electronic device of claim 11, wherein the computer-executable instruction further causes the electronic device to execute:
generating a data dictionary corresponding to the data split, wherein the data dictionary represents a marking manner for the number of the identical binary symbols in the data split, and represents the preset arrangement manner for the marked number and the content of the identical binary symbols; and
sending the data dictionary; or sending an indicator of the data dictionary, wherein the indicator of the data dictionary represents the data dictionary corresponding to the data split.

13. The electronic device of claim 10, wherein the computer-executable instruction further causes the electronic device to execute:
before sending the abbreviated data,
acquiring other data in the binary data other than the data split;
obtaining a length of binary data occupied by a same repetition pattern in the other data;
determining a repetition pattern occupying the longest length of binary data as a target pattern; and
abbreviating the target pattern to obtain an abbreviated pattern data;
wherein in terms of sending the abbreviated data, the computer-executable instruction causes the electronic device to execute:
sending the abbreviated data, wherein the abbreviated data comprises the abbreviated data split and the abbreviated pattern data.

14. The electronic device of claim 13, wherein the computer-executable instruction further causes the electronic device to execute:
generating a data dictionary corresponding to the other data, wherein the data dictionary represents a corresponding relationship between the target pattern and the abbreviated pattern data; and
sending the data dictionary; or sending an indicator of the data dictionary, wherein the indicator of data dictionary represents the data dictionary corresponding to the other data.

15. The electronic device of claim 13, wherein the computer-executable instruction further causes the electronic device to execute:
determining a secondary target pattern according to a length of binary data occupied by a same repetition pattern, wherein the secondary target pattern is a repetition pattern occupying a length of binary data second only to the target pattern; and
abbreviating the secondary target pattern to obtain a secondary abbreviated pattern data;
wherein in terms of sending the abbreviated data, the computer-executable instruction causes the electronic device to execute:
sending the secondary abbreviated data, wherein the secondary abbreviated data comprises the abbreviated data split, the abbreviated pattern data, and the secondary abbreviated pattern data.

16. The electronic device of claim 10, wherein the computer-executable instruction further causes the electronic device to execute:
acquiring a first duration corresponding to abbreviating the data split;
acquiring an estimated second duration corresponding to sending the abbreviated data split; and
splitting the data split into a plurality of data sub-splits in response to a difference between the first duration and the second duration being greater than a preset duration;
wherein in terms of abbreviating the data split, the computer-executable instruction causes the electronic device to execute:
abbreviating all or some of the plurality of data sub-splits.

17. A non-transitory computer-readable storage medium, wherein the non-transitory computer-readable storage medium stores a computer instruction, and the computer instruction, when executed on a communication device, causes the communication device to execute:
acquiring original data;
performing a binary conversion on the original data to obtain binary data;
scanning the binary data, matching the binary data with the preset rule, and separating binary data that is successfully matched with the preset rule into a data split;
abbreviating the data split to obtain an abbreviated data split; and
sending abbreviated data, wherein the abbreviated data comprises the abbreviated data split.

18. The non-transitory computer-readable storage medium of claim 17, wherein the preset rule is that a data split consists of identical binary symbols and a number of the identical binary symbols is greater than a preset number, and wherein in terms of matching the binary data with the preset rule, and separating the binary data that is successfully matched with the preset rule into the data split, the computer instruction causes the communication device to execute:
acquiring a first binary data section, wherein the first binary data section consists of a plurality of identical binary symbols, and a binary symbol is 0 or 1;
determining that the first binary data section is successfully matched with the preset rule in response to a number of the identical binary symbols in the first binary data section being greater than the preset number; and
determining the first binary data section as the data split.

19. The non-transitory computer-readable storage medium of claim 18, wherein in terms of abbreviating the data split, the computer instruction causes the communication device to execute:
acquiring a content and the number of the identical binary symbols in the data split;
marking the number of the identical binary symbols to obtain a marked number, wherein the marked number is in a binary form; and
determining the abbreviated data split, wherein the abbreviated data split comprises the marked number and the content of the identical binary symbols that are arranged in a preset arrangement manner.

20. The non-transitory computer-readable storage medium of claim 19, wherein the computer instruction further causes the communication device to execute:
generating a data dictionary corresponding to the data split, wherein the data dictionary represents a marking manner for the number of the identical binary symbols in the data split, and represents the preset arrangement manner for the marked number and the content of the identical binary symbols; and
sending the data dictionary; or sending an indicator of the data dictionary, wherein the indicator of the data dictionary represents the data dictionary corresponding to the data split.
